(19) United States
(12) Patent Application Publication
(10) Pub. No.: US 2025/0192768 A1
(43) Pub. Date: Jun. 12, 2025

(54) CONTROL SYSTEM FOR CONTROLLING A TRANSISTOR, ELECTRIC VEHICLE COMPRISING THE CONTROL SYSTEM, METHOD FOR CONTROLLING THE TRANSISTOR

(71) Applicant: Lightyear IPCo B.V., Helmond (NL)

(72) Inventor: Marald OTTEN, Eindhoven (NL)

(21) Appl. No.: 18/846,534

(22) PCT Filed: Mar. 28, 2023
(86) PCT No.: PCT/EP2023/058042

§ 371 Date: Sep. 12, 2024

(30) Foreign Application Priority Data
Mar. 29, 2022 (NL) 2031425

(51) Int. Cl. H03K 17/16; H03K 17/0812

(52) U.S. Cl. CPC H03K 17/165; H03K 17/08122

(57) ABSTRACT

Control system for controlling a transistor comprising a gate, comprising a control unit adapted to connect a voltage supply to the gate via a first electrical path to allow the voltage supply to supply a first voltage to the transistor when the transistor is in a first state, control the voltage supply to apply the first voltage via the first electrical path to the transistor to switch the transistor from the first state to a second state, disconnect the voltage supply and the gate from each other, connect the voltage supply to the gate to allow the voltage supply to supply a second voltage via the second electrical path to the transistor when the transistor is in the second state, control the voltage supply to apply the second voltage to the gate, wherein the second electrical path is adapted to conduct a current from the voltage supply to the transistor based on a leakage current of the transistor.

The invention relates to a control system for controlling a transistor comprising a gate, a source and a drain. The intention further relates to an electric vehicle comprising the control system. Further, the invention relates to a method for controlling the transistor.

A transistor is a semiconductor device used to amplify or switch electrical signals and power. The transistor is one of the basic building blocks of modern electronics. The most widely used type of transistor is the metal-oxide-semiconductor field-effect transistor (MOSFET). However, there are several types of transistors, for example bipolar transistors, HEMT (high-electron-mobility transistor) devices. HEMT devices, such as GaN HEMT, are characterized by their relatively high electron mobility. The high electron mobility of HEMT helps to achieve higher gain, which makes them useful as amplifiers. HEMT also offers high switching speeds. Therefore, HEMT are popular to integrate in electric systems of electric vehicles, such as electric cars.

However, HEMT devices suffer from the disadvantage that the leakage current, which runs between the gate and source of the HEMT device, depends on the temperature. For an increase up to 80° C. the leakage current decreases because of deep acceptor initiated impact ionization. The leakage current slowly starts to increase again when the temperature is raised and increases exponential around 150° C. due to the tunneling of electrons through to the gate. At that moment the device experiences a short circuit. Under normal operation conditions, these kind of temperatures are not uncommon.

The transistor, and the HEMT device in particular, has the drawback to be sensitive to currents well exceeding the current under normal operation conditions. Due to the high temperature, a short circuit of the transistor is likely to occur. For example, GaN devices can withstand short circuits for only hundreds of nanoseconds. When the short circuit occurs for only this short period of time in the transistor, the transistor becomes damaged or even fails. Furthermore, it is difficult to detect the short circuit. Due to these drawbacks, a timely anticipation before any damage relating to the transistor occurs due to the short circuit is hard to achieve.

It is an objective of the invention to provide a control system for controlling a transistor that is less affected by the disadvantage mentioned above, or to provide at least an alternative control system.

The objective of the invention is achieved by a control system for controlling a transistor comprising a gate, a source and a drain, the control system comprising:
a gate connector connectable to the gate of the transistor;
a voltage connector connectable to a voltage supply;
a first electrical path extending from the voltage connector to the gate connector;
a second electrical path extending from the voltage connector to the gate connector, wherein the second electrical path comprises a first resistive component, wherein the first electrical path and the second electrical path are at least partly parallel to each other;
   wherein the control system further comprises a control unit which is adapted to:
connect the voltage supply to the gate via the first electrical path to allow the voltage supply to supply a first voltage via the first electrical path to the gate connector when the transistor is in a first state;
control the voltage supply to apply the first voltage via the first electrical path to the gate connector to switch the transistor from the first state to a second state;
disconnect the voltage supply and the gate from each other via the first electrical path when the transistor is in the second state;
connect the voltage supply to the gate via the second electrical path to allow the voltage supply to supply a second voltage via the second electrical path to the gate connector when the transistor is in the second state;
control the voltage supply to apply the second voltage via the second electrical path to the gate connector, wherein the second electrical path is adapted to conduct a current from the voltage connector via the first resistive component to the gate connector based on a leakage current of the transistor.

The invention thus relates to a control system for controlling a transistor comprising a gate, a source and a drain. The transistor is for example a GaN HEMT. The HEMT device is typically powered on when the voltage between the gate and source exceeds a threshold voltage. The threshold voltage of a GaN HEMT lies around 2V. This behaviour is called the enhancement mode (e-mode device or eHEMT). When the voltage between the gate and source is less than the threshold voltage, such a transistor is turned off. This kind of mode is known as the depletion mode (d-mode device or dHEMT).

The control system comprises a gate connector connectable to the gate of the transistor. For example, the gate connector is connected to the gate of the transistor through a switch. For example, the gate connector is connected to the gate of the transistor by soldering the gate connector to the gate. The source or the drain is connectable to a load. The load can be either inductive for example a power boost converter or motor, or resistive for example a heater.

The control system further comprises a voltage connector connectable to a voltage supply. The voltage connector is for example a switch. The voltage connector is for example a plug or switch-plug. The voltage supply is e.g. a DC voltage supply derived from a mains supply by means of an AC/DC converter. The voltage supply comprises, for example, a battery. The voltage supply for example applies a voltage of 5 V to the voltage connector.

The control system further comprises a first electrical path extending from the voltage connector to the gate connector. The first electrical path is for example an electric wire able to transfer a voltage or current from the voltage connector to the gate connector. The voltage supply is configured to supply a first voltage via the first electrical path to the gate of the transistor by connecting the voltage supply to the voltage connector and the gate connector to the gate.

The control system further comprises a second electrical path extending from the voltage connector to the gate connector. The second electrical path is for example an electric wire able to transfer a voltage or current from the voltage connector to the gate connector. The voltage supply is configured to supply a second voltage via the second electrical path to the gate of the transistor by connecting the voltage supply to the voltage connector and the gate connector to the gate. The second electrical path comprises a first resistive component, for example a resistor. The first electrical path and the second electrical path are at least partly parallel to each other. In an example, the first electrical path and the second electrical path are parallel to each other between the voltage connector and the gate connector.

The control system further comprises a control unit. The control unit is adapted to connect the voltage supply to the gate via the first electrical path to allow the voltage supply to supply a first voltage via the first electrical path to the gate connector when the transistor is in a first state. The first state is for example the situation wherein the transistor is “off”, meaning that no current is flowing between the drain and the source. The control unit controls the voltage supply to apply the first voltage via the first electrical path to the gate connector. When the voltage supply supplies the first voltage to the transistor, the voltage at the gate will become equal to the first voltage. This can for example take place almost instantaneously. The first voltage is e.g. 5 V. By having the first voltage at the gate, the transistor is switched from the first state to a second state. The transistor is for example turned on in the second state, wherein current is flowing between the drain and the source. The current flowing between the drain and the source is also referred as the forward current.

When the transistor is in the second state, the transistor is for example “on”, the control unit is adapted to disconnect the voltage supply and the gate from each other via the first electrical path. Further, the control unit is adapted to connect the voltage supply to the gate via the second electrical path to allow the voltage supply to supply a second voltage via the second electrical path to the gate connector when the transistor is in the second state. The second voltage is e.g. 5 V. The second voltage is sufficiently high to keep the transistor in the second state, and to prevent the transistor from returning to the first state. For example, the control unit is adapted to provide the second voltage to the gate when disconnecting the voltage supply and the gate from each other via the first electrical path, to keep the transistor in the second state.

The control unit is adapted to control the voltage supply to apply the second voltage via the second electrical path to the gate connector. The second electrical path is adapted to conduct a current from the voltage connector via the first resistive component to the gate connector based on a leakage current of the transistor. By applying the second voltage to the gate connector, the transistor is held in the second state. In the second state, a forward current flows between the source and the drain. The forward current induces heat in the transistor, increasing the temperature of the transistor. As a consequence of the increase in temperature, a leakage current starts to flow between the gat and the source. The leakage current increases as a function of the temperature. Because the second electrical path is connected to the gate connector, the leakage current not only flows between the gate and the drain, but also from the voltage supply to the gate via the second electric path. The first resistive component is arranged to cause a voltage drop based on the leakage current. The voltage drop over the first resistive component increases together with the increasing leakage current. For example, at 150° C. the leakage current may be 1 mA. The voltage drop over the first resistive component, for example a resistor with a resistance value of 1 kOhm, will then be 1 V. As a result of the voltage drop over the first resistive component, the voltage at the gate is reduced. By reducing the voltage at the gate, the leakage current is reduced. This way, a large leakage current is prevented, which prevents damage to the transistor.

In an embodiment, the first resistive component is arranged to reduce, in response to the current, the gate voltage at the gate connector to a value lower than the first voltage to switch the transistor from the second state to the first state. For example, the voltage at the gate is reduced with 1 V. As a result, the gate voltage is reduced causing the voltage at the gate to be insufficient to power the transistor, whereby the transistor is switched from the second state to the first state. Because the transistor is off in the first state, there is no forward current flowing in the first state. As a result, the temperature of the transistor will decrease, further reducing the leakage current.

In an embodiment, the control system further comprises a discharging switch. The discharging switch is arranged between the first electrical path and/or the second electrical path and a ground to connect the first electrical path to the ground and/or to connect the second electrical path to the ground. The discharging switch is for example a bipolar transistor. When the voltage supply is supplying the first voltage via the first electrical path or the second voltage via the second electrical path to the gate of the transistor, the discharging switch is open. When the discharging switch is open, no current is drained away to the ground via the discharging switch from the first electrical path or the second electrical path. At the moment the transistor is switched from the second state to the first state due to the voltage drop, the discharging switch is closed. In the closed state of the discharging switch, the discharging switch discharges the gate of the transistor. The control unit is for example configured to control the switching of the discharging switch.

When the transistor switches back to the first state due to the voltage drop, there may be still a remaining voltage applied to the gate. The remaining voltage is lower than the first voltage. The remaining voltage may cause the leakage current to continue. By discharging the gate with the discharging switch, the remaining voltage is removed from the gate, causing the leakage current to stop. This way, the control system provides a safer manner of controlling the transistor.

In an embodiment, the control system further comprises a first switch arranged in the first electrical path to connect the voltage supply to the gate via the first electrical path. According to this embodiment, the first switch is configured to make a connection between the voltage supply and the gate to allow the voltage supply to apply the first voltage to the gate. The first switch is for example a bipolar transistor. For example, the control unit is configured to control the first switch by closing the first switch between the voltage supply and the gate.

In an embodiment, the control system comprises a pull-up driver, wherein the first switch is controlled by the pull-up driver adapted to generate a pulse to switch the first switch. For example, by applying a high pulse the first switch is closed and by applying a low pulse the first switch is open. The pulse is for example generated by a first order high pass filter. The pulse is for example generated digitally. The pull-up driver is for example integrated in the control unit. The pull-up driver is associated with a relatively high drive current. This allows the pull-up driver to drive the transistor, for example a HEMT device, in a fast way.

In an embodiment, the first electrical path comprises a second resistive component. The second resistive component is for example a resistor. When the voltage supply is connected to the gate via the first electrical path, the first electrical path is adapted to conduct current from the voltage connector via the second resistive component to the gate connector. The second resistive component allows to power the transistor gradually until the gate voltage is equal to the first voltage. This prevents an abrupt change in the gate voltage.

In an embodiment, the second resistive component has a lower resistance value than the first resistive component. Because the second resistive component has the lower resistance value, the voltage supply creates a large current over the first electrical path when applying the first voltage. As a result of the large current, the voltage at the gate is quickly increased to the first voltage. This allows a quick switching of the transistor. In comparison, if the second resistive component would have a high resistance value, the switching of the transistor would take long. Because the first resistive component has the higher resistance value, even a small leakage current causes a relatively large voltage drop. This helps to create a sufficient voltage drop at the gate to reduce the leakage current even for a small leakage current. The voltage drop may be sufficient to switch the transistor back from the second state to the first state. This helps to protect transistors that are sensitive to small leakage currents. For example, the resistance value of the second resistive component is between 1-10 Ohm, preferably between 1-5 Ohm. For example, the resistance value of the first resistive component is between 100-2000 Ohm, preferably between 500-1500 Ohm.

In an embodiment, the first electrical path and the second electrical path are arranged in serial connection to the gate of the transistor. The first electrical path and the second electrical path may partly overlap with each other. By arranging the first electrical path and the second electrical path in serial connection to the gate, the gate needs only a single connection to connect to both the first electrical path and the second electrical path. This allows for a simple connection between the control system and the transistor.

In an embodiment, the control system further comprises a second switch arranged in the second electrical path to connect the voltage supply to the gate via the second electrical path. According to this embodiment, the second switch is configured to make a connection between the voltage supply and the gate to allow the voltage supply to apply the second voltage to the gate. The second switch is for example a bipolar transistor. For example, the control unit is configured to control the second switch by closing the second switch between the voltage supply and the gate.

For example, when the transistor is in the second state, the transistor is “on”, the control unit is adapted to disconnect the voltage supply and the gate from each other via the first electrical path, for example by controlling the first switch to switch the first switch open. Further, the control unit is adapted to connect the voltage supply to the gate by closing the second switch between the voltage supply and the gate. In this way, the voltage is allowed to supply via the second electrical path the second voltage to the gate connector when the transistor is in the second state. The second voltage is e.g. 5 V.

In an embodiment, the control system further comprises a leakage current detection system configured to determine the leakage current of the transistor based on a voltage over the first resistive component. Because the first resistive component causes the voltage drop as a result of the leakage current, the voltage over the first resistive component provides an easy to measure quantity that represents the leakage current. Especially when the first resistive component has a high resistance value, the leakage current can be accurately determined by detecting the voltage over the first resistive component. The leakage current detection system for example measures the voltage drop over the first resistive component.

The leakage current detection system is for example configured to compare the measured voltage drop over the first resistive component with a predetermined reference voltage. The predetermined reference voltage is for example selected to represent a leakage current that could cause damage to the transistor. The predetermined reference voltage is e.g. set at 1 V.

In a further embodiment, the leakage current detection system is configured to provide a signal representative of the leakage current of the transistor to the control unit. The control unit is configured, in response of the signal, to switch the transistor from the second state to the first state. For example, when the leakage current of the transistor reaches a level which could be detrimental for the transistor, the leakage current detection system is configured to provide a signal to the control unit. In response of the signal, the control unit for example turns the transistor off, e.g. by disconnecting the voltage supply from the gate. For example, the control unit controls the second switch, in response of the signal, to disconnect the voltage supply from the gate connector. The signal from the leakage current detection system serves as a feedback signal. For example, the leakage current detection system continuously monitors the voltage drop over the first resistive component. In this way, the control system is adapted to anticipate more quickly to high leakage currents.

For example, the control unit is adapted to control the discharging switch. In response to the signal, the control unit for example controls the discharging switch to connect the gate of the transistor to the ground. In response to the signal, the control unit, for example, controls the discharging switch to connect the first electrical path to the ground and/or to connect the second electrical path to the ground.

In a further embodiment, the signal representative of the leakage current of the transistor is representative of a short circuit of the transistor. As mentioned earlier, transistors and especially HEMT devices can withstand short circuits for only a short period of time. As soon as the leakage current reaches a level which is representative of the short circuit of the transistor, the leakage current detection system for example provides the signal to the control unit. In response to the received signal, the control unit switches the transistor from the second state to the first state.

In an embodiment, the transistor is a HEMT, preferably a GaN HEMT. According to this embodiment, the control system is adapted to control a HEMT-transistor. HEMT-transistors are able to switch at a high frequency and to conduct large forward currents. However, when reaching a certain temperature, the leakage current of a HEMT-transistor increases rapidly. A high leakage current is able to damage the HEMT-transistor in a very short amount of time. Typical safety mechanisms are not able to respond within this short amount of time to prevent damage to the HEMT-transistor. By providing the control system, the leakage current is reduced or removed automatically because of the voltage drop over the first resistive component. This way the protection of the HEMT-transistor is improved.

In an embodiment, there is provided an electric vehicle comprising the control system according to any of the embodiments disclosed above. By using the control system in an electric vehicle, the electric vehicle can be operated in a safer way, because the risk of damage to a transistor in the electric vehicle is reduced or eliminated.

In an embodiment, the electric vehicle comprises an inverter or power converter and at least one of a drive train and a solar panel. The inverter or power converter comprises the transistor. The drive train is for providing power to drive the electric vehicle. The solar panel is for generating electric energy based on solar energy. The inverter or power converter is adapted to exchange electric energy with at least one of the drive train and the solar panel.

According to this embodiment, the transistor is involved in transferring electric energy with the drive train or the solar panel. Typically for an electric vehicle, this transfer of electric energy involves large currents. The large currents pose the risk of increasing the temperature of the transistor, resulting in a high leakage current. By providing the control system, damage to the transistor by an unacceptable high leakage current is reduced or prevented.

In a further aspect of the invention, there is provided a method for controlling a transistor comprising a gate, a source and a drain, comprising the steps of:
supplying a first voltage via a first electrical path to the gate when the transistor is in a first state;
switching the transistor from the first state to a second state in response to the first voltage;
stop providing the first voltage to the gate via the first electrical path when the transistor is in the second state;
supplying a second voltage to the gate via a second electrical path when the transistor is in the second state, wherein the second electrical path comprises a first resistive component, and wherein the first electrical path and the second electrical path are at least partly in parallel to each other;
conducting a current via the first resistive component to the gate based on a leakage current of the transistor.

According to the further aspect of the invention, the first electrical path is able to transfer a first voltage to the gate of the transistor when the transistor is in a first state. The first voltage is for example supplied by a voltage supply. In the first state the transistor for example is turned off. Due to the applied first voltage at the gate, the transistor switches from the first state to a second state. In the second state, the transistor for example turns on. In case the transistor is the second state, it is stopped to provide the first voltage to the gate via the first electrical path and a second voltage is supplied to the gate via a second electrical path. The second electrical path comprises a first resistive component, for example a resistor. A current flows via the first resistive component to the gate based on a leakage current of the transistor. In case the leakage current flows between the first resistive component and the gate, the leakage current induces a voltage drop across the first resistive component. The leakage current becomes higher when the temperature increases due to the forward current. Because the leakage current increases, the voltage drop over the first resistive component becomes higher. As a result, the voltage at the gate decreases, which helps to reduce the leakage current. In case the leakage current reaches a dangerous level for the transistor, the associated voltage drop across the first resistive component causes the transistor to switch from the second state to the first state. Because the transistor is automatically switched off when the leakage current becomes too high, the invention improves the safety and lifetime relating to the transistor.

In an embodiment, the method further comprising the step of:
determining the leakage current of the transistor based on a voltage over the first resistive component.

According to this embodiment, the leakage current flowing between the gate and the source is determined. This provides feedback about the value of the leakage current.

According to a further embodiment, the step of determining the leakage current of the transistor based on a voltage over the first resistive component comprises comparing the voltage over the first resistive component with a reference voltage representative of a short circuit of the transistor. In case that the voltage over the first resistive component exceeds the reference voltage, the leakage current running through the transistor causes short circuit of the transistor. In this way, it is ensured that the transistor immediately is switched from the second state to the first state when the short circuit occurs.

In an embodiment, the method further comprises the step of:
reducing a gate voltage at the gate to a value lower than the second voltage to switch the transistor from the second state to the first state after determining the leakage current.

In an embodiment, the method further comprises the step of:
creating a voltage drop over the first resistive component in response to the current to reduce the gate voltage.

The invention is described below with reference to the figures. These figures serve as examples to illustrate the invention, and will not be construed as limiting the scope of the claims. In the different figures, like feature are indicated by the like reference numerals.

In the figures:

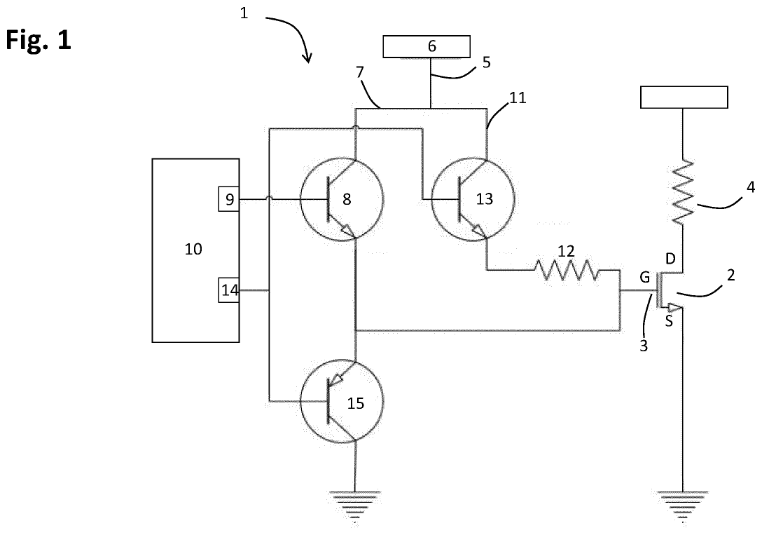

FIG. 1: Schematically illustrates a first embodiment of a control system according to the invention;

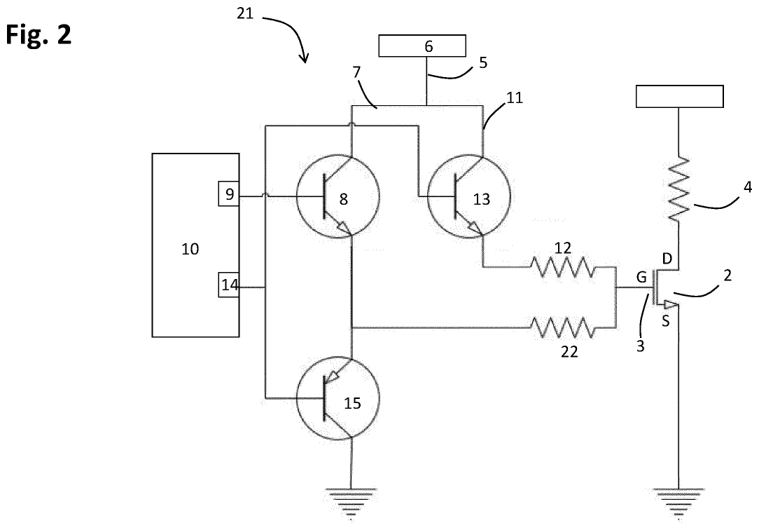

FIG. 2: Schematically illustrates a second embodiment of a control system according to the invention;

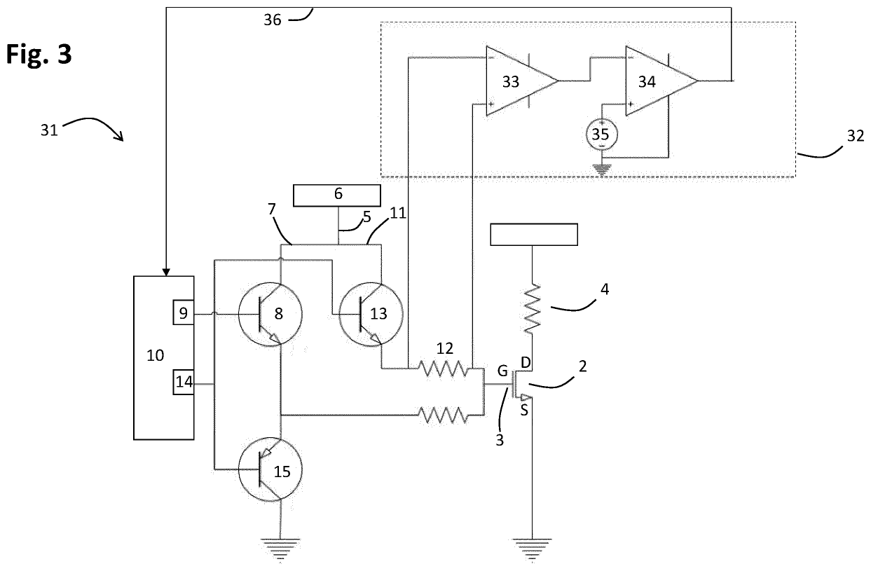

FIG. 3 Schematically illustrates a third embodiment of a control system according to the invention;

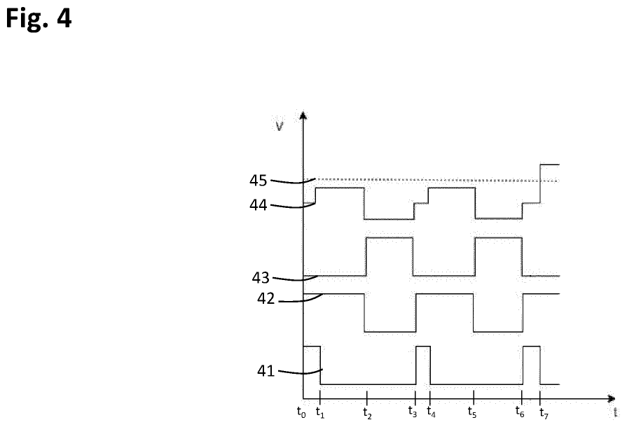

FIG. 4: Schematically illustrates an embodiment of a switching behaviour as a function of time associated with a first switch, second switch and discharging switch of a control system according to the invention;

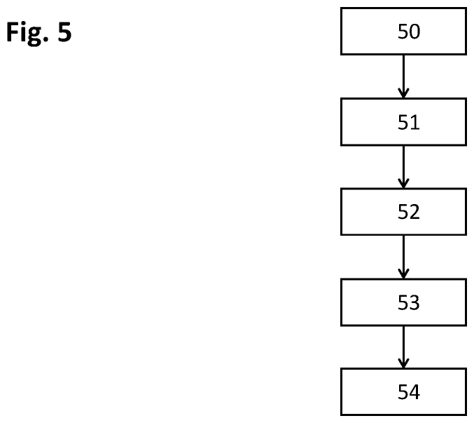

FIG. 5: Schematically illustrates an embodiment of a flow diagram of the method according to the invention.

FIG. 1 illustrates a first embodiment of a control system 1 for controlling a transistor 2. The transistor 2 comprises a gate G, a source S and a drain D. The transistor 2 is for example a GaN HEMT. The control system 1 comprises a gate connector 3 connectable to the gate G of the transistor 2. For example, the gate connector 3 is connected to the gate G of the transistor 2 by soldering the gate connector 3 to the gate G. The drain D is connected to a load 4. The load 4 is for example an inductive load, for example a power boost converter or motor. Alternatively, the load 4 is resistive, for example a heater.

The control system further 1 comprises a voltage connector 5 connectable to a voltage supply 6. The voltage connector 5 is for example a plug or switch-plug. In FIG. 1, the voltage supply 6 is a DC voltage supply. In an embodiment, the voltage supply 6 comprises, for example, a battery. The voltage supply 6 for example applies a voltage of 5 V to the voltage connector 5.

The control system 1 further comprises a first electrical path 7 extending from the voltage connector 5 to the gate connector 3. The first electrical path 7 comprises an electric wire able to transfer a voltage or current from the voltage connector 5 to the gate connector 3. The voltage supply 6 is configured to supply a first voltage, e.g. 5 V, via the first electrical path 7 to the gate G of the transistor 2. The control system 1 further comprises a first switch 8 arranged in the first electrical path 7 to connect the voltage supply 6 to the gate G via the first electrical path 7. The first switch 8 is configured to make a connection between the voltage supply 6 and the gate G to allow the voltage supply 6 to apply the first voltage to the gate G. In FIG. 1, the first switch 8 is a NPN bipolar transistor. The first switch 8 is controlled by a pull-up driver 9 adapted to generate a pulse to switch the first switch 8. For example, by applying a high pulse the first switch 8 is closed and by applying a low pulse the first switch 8 is open. The pull-up driver 9 is integrated in a control unit 10. When the first switch 8 is closed, the first switch 8 allows a current to flow through the first switch 8 along the first electrical path 7. When the first switch 8 is open, the first switch 8 interrupts the first electrical path 7.

The control system 1 further comprises a second electrical path 11 extending from the voltage connector 5 to the gate connector 3. The second electrical path 11 comprises an electric wire able to transfer a voltage or current from the voltage connector 5 to the gate connector 3. The voltage supply 6 is configured to supply a second voltage, e.g. 5 V, via the second electrical path 11 to the gate G of the transistor 1. The second electrical path 11 comprises a first resistive component 12. In FIG. 1, the first resistive component 12 is a resistor. The first electrical path 7 and the second electrical path 11 are at least partly parallel to each other between the voltage connector 5 and the gate connector 3. A second switch 13 is arranged in the second electrical path 11 to connect the voltage supply 6 to the gate G via the second electrical path 11. The second switch 13 is configured to make a connection between the voltage supply 6 and the gate G to allow the voltage supply 6 to apply the second voltage to the gate G. In FIG. 1, the second switch 13 is a NPN bipolar transistor. The switching of the second switch 13 is controlled via a PWM (pulse width modulation) controller 14. The PWM controller 14 is integrated in the control unit 10.

The control system 1 further comprises the control unit 10. The control unit 10 controls the first switch 8 by closing the first switch 8 to connect the voltage supply 6 to the gate G via the first electrical path 7 to allow the voltage supply 6 to supply a first voltage via the first electrical path 7 to the gate connector 3 when the transistor 2 is in a first state. The first state is for example the situation wherein the transistor 2 is “off”, meaning that no current is flowing between the drain D and the source S. The control unit 10 controls the voltage supply 6 to apply the first voltage via the first electrical path 7 to the gate connector 3. When the voltage supply 6 supplies the first voltage to the transistor 2, the voltage at the gate G will become equal to the first voltage. This can for example take place almost instantaneously. By having the first voltage at the gate G, the transistor 2 is switched from the first state to a second state. The transistor 2 is for example turned on in the second state, wherein forward current is flowing between the drain D and the source S.

When the transistor 2 is in the second state, the transistor 2 is for example “on”, the control unit 10 disconnects the voltage supply 6 and the gate G from each other via the first electrical path 7 by opening the first switch 8. Almost simultaneously, the control unit 10 controls the second switch 13 by closing the second switch 13 to connect the voltage supply 6 to the gate G via the second electrical path 11 to allow the voltage supply 6 to supply a second voltage via the second electrical path 11 to the gate connector 3 when the transistor 2 is in the second state. By providing the second voltage to the gate G when disconnecting the voltage supply 6 and the gate G from each other via first electrical path 7, the transistor 2 is kept in the second state. The second voltage is e.g. 5 V. The second voltage is sufficiently high to keep the transistor 2 in the second state, and to prevent the transistor 2 from returning to the first state.

By providing the second voltage to the gate G, the second electrical path 11 conducts a current from the voltage connector 5 via the first resistive component 12 to the gate connector 3 based on a leakage current of the transistor 2. By applying the second voltage to the gate connector 3, the transistor 2 is held in the second state. In the second state, a forward current flows between the source S and the drain D. The forward current induces heat in the transistor 2, increasing the temperature of the transistor 2. As a consequence of the increase in temperature, a leakage current starts to flow between the gate G and the source S. The leakage current increases as a function of the temperature. Because the second electrical path 11 is connected to the gate connector 3, the leakage current not only flows between the gate G and the drain D, but also from the voltage supply 6 to the gate G via the second electric path 11. The first resistive component 12 causes a voltage drop based on the leakage current. The voltage drop over the first resistive component 12 increases together with the increasing leakage current. For example, at 150° C. the leakage current may be 1 mA. The voltage drop over the first resistive component 12, for example having a resistance value of 1 kOhm, will then be 1 V. As a result of the voltage drop over the first resistive component 12, the voltage at the gate G is reduced. By reducing the voltage at the gate G, the leakage current is reduced. This way, a large leakage current is prevented, which prevents damage to the transistor 2.

The first resistive component 12 reduces, in response to the leakage current, the gate voltage at the gate connector 3 to a value lower than the first voltage to switch the transistor 2 from the second state to the first state. For example, the voltage at the gate G is reduced with 1 V. As a result, the gate voltage is reduced causing the voltage at the gate G to be insufficient to power the transistor 2, whereby the transistor 2 is switched from the second state to the first state. Because the transistor 2 is off in the first state, there is no forward current flowing in the first state. As a result, the temperature of the transistor 2 will decrease, further reducing the leakage current.

The control system 1 further comprises a discharging switch 15. The discharging switch 15 is arranged to connect the first electrical path 7 to the ground and/or to connect the second electrical path 11 to the ground. The discharging switch 15 is able to connect the first electrical path 7 to the ground. The discharging switch 15 is able to connect the second electrical path 11 to the ground. The discharging switch 15 is a PNP bipolar transistor. When the voltage supply 6 is supplying the first voltage via the first electrical path 7 or the second voltage via the second electrical path 11 to the gate G of the transistor 2, the discharging switch 15 is open. When the discharging switch 15 is open, no current is drained away to the ground via the discharging switch 15 from the first electrical path 7 or the second electrical path 11. At the moment the transistor 2 is switched from the second state to the first state due to the voltage drop, the discharging switch 15 is closed. Additionally, the control unit 10 is configured to open the second switch 13 to disconnect the voltage supply 6 from the gate G of the transistor 2. In the closed state of the discharging switch 15, the discharging switch 15 discharges the gate G of the transistor 2. The control unit 10 controls the switching of the discharging switch 15 via the same PWM signal as provided to the second switch 13, whereby both switches are operated at the same time. When the second switch 13 is closed, the discharging switch 15 is opened to prevent that current is drained away to the ground. When the second switch 13 is switched open, the discharging switch 15 is closed to discharge the gate.

When the transistor 2 switches back to the first state due to the voltage drop, there may be still a remaining voltage applied to the gate G. The remaining voltage is lower than the first voltage. The remaining voltage may cause the leakage current to continue. By discharging the gate G with the discharging switch 15, the remaining voltage is removed from the gate G, causing the leakage current to stop. This way, the control system 1 provides a safer manner of controlling the transistor 2.

FIG. 2 shows a second embodiment of a control system 21 for controlling a transistor. The features of the control system 21 corresponding with those of the control system 1 shown in FIG. 1 are indicated with the same reference numerals in FIG. 2.

In FIG. 2, the first electrical path 7 comprises a second resistive component 22. The second resistive component 22 is a resistor. When the voltage supply 6 is connected to the gate G via the first electrical path 7, the first electrical path 7 is adapted to conduct current from the voltage connector 5 via the second resistive component 22 to the gate connector 3. The second resistive component 22 allows to power the transistor 2 gradually until the gate voltage is equal to the first voltage. This prevents an abrupt change in the gate voltage.

The second resistive component 22 has a lower resistance value than the first resistive component 12. Because the second resistive component 22 has the lower resistance value, the voltage supply 6 creates a large current over the first electrical path 7 when applying the first voltage. As a result of the large current, the voltage at the gate G is quickly increased to the first voltage. This allows a quick switching of the transistor 2. In comparison, if the second resistive component 22 would have a high resistance value, the switching of the transistor 2 would take long. Because the first resistive component 12 has the higher resistance value, even a small leakage current causes a relatively large voltage drop. This helps to create a sufficient voltage drop at the gate G to reduce the leakage current even for a small leakage current. The voltage drop may be sufficient to switch the transistor 2 back from the second state to the first state. This helps to protect transistors that are sensitive to small leakage currents. For example, the resistance value of the second resistive component 22 is between 1-10 Ohm, preferably between 1-5 Ohm. For example, the resistance value of the first resistive component 12 is between 100-2000 Ohm, preferably between 500-1500 Ohm.

FIG. 3 shows a third embodiment of a control system 31 for controlling a transistor. The features of the control system corresponding with those of the control system shown in FIGS. 1-2 are indicated with the same reference numerals in FIG. 3.

In FIG. 3, the control system 31 comprises a leakage current detection system 32. The leakage current detection system 32 is configured to determine the leakage current of the transistor 2 based on a voltage over the first resistive component 12. Because the first resistive component 12 causes the voltage drop as a result of the leakage current, the voltage over the first resistive component 12 provides an easy to measure quantity that represents the leakage current. Especially when the first resistive component 12 has a high resistance value, the leakage current can be accurately determined by detecting the voltage over the first resistive component 12. The leakage current detection system 32 measures the voltage drop over the first resistive component 12.

In FIG. 3, the leakage current detection system 32 comprises a first operational amplifier 33 (opamp) and a second operation amplifier (opamp) 34, which are connected in serial connection. The first opamp 33 outputs the voltage over the first resistive component to the second opamp 34. The second opamp 34 corresponds to an op-amp voltage comparator. The second opamp 34 compares the voltage, representing the measured voltage drop over the first resistive component 12, with a predetermined reference voltage 35. The predetermined reference voltage 35 is for example selected to represent a leakage current that could cause damage to the transistor 2. The predetermined reference voltage 35 is e.g. set at 1 V.

Additionally, the leakage current detection system 32 is configured to provide a signal 36 representative of the leakage current of the transistor to the control unit 10. The second opamp 34 outputs for example a digital signal 36 indicating which of the compared voltages, i.e. the voltage over the first resistive component 12 and the predetermined reference voltage 35, is larger. If the voltage over the first resistive component 12 is lower than the reference voltage 35, the second opamp 34 outputs a digital “low”. This represents the situation wherein the value of the leakage current is acceptable. If the measured voltage is larger than the reference voltage 35, the second opamp 34 outputs a digital “high”. This represents the situation wherein the value of the leakage current is unacceptable. The control unit 10 is configured, in response of the signal 36, to switch the transistor 2 from the second state to the first state. For example, when the leakage current of the transistor 2 reaches a level which could be detrimental for the transistor 2, the leakage current detection system 32 provides a “high” signal 36 to the control unit 10. In response of the signal 36, the control unit 10 turns the transistor 2 off, e.g. by disconnecting the voltage supply 6 from the gate G. For example, the control unit 10 controls the second switch 13, in response of the signal 36, to disconnect the voltage supply 6 from the gate connector 3. The signal 36 from the leakage current detection system 32 serves as a feedback signal. For example, the leakage current detection system 32 continuously monitors the voltage drop over the first resistive component 12. In this way, the control system 31 is adapted to anticipate more quickly to high leakage currents.

Additionally, in response to the signal 36, the control unit 10 controls the discharging switch 15 to connect the gate G of the transistor 2 to the ground. In response to the signal 36, the control unit 10, for example, controls the discharging switch 15 to connect the first electrical path 7 to the ground and/or to connect the second electrical path 11 to the ground.

In a further embodiment, the signal 36 representative of the leakage current of the transistor 2 is representative of a short circuit of the transistor 2. As soon as the leakage current reaches a level which is representative of the short circuit of the transistor 2, the leakage current detection system 32 provides the signal 36 to the control unit 10. In response to the received signal, the control unit 10 switches the transistor 2 from the second state to the first state.

FIG. 4 schematically illustrates an embodiment of a switching behaviour as a function of time associated with a first switch 8, second switch 13 and discharging switch 15 of a control system according to the invention. The control system is for example the control system 31 illustrated in FIG. 3.

In FIG. 4 logic signals are disclosed associated with the first switch 41, the second switch 42 and the discharging switch 43. These logic signals 41, 42, 43 are expressed in on/off signals. When the signal is high, i.e. the signal represents a digital “1”, the respective switch is switched on (i.e. the switch is closed). When the signal is low, i.e. the signal represents a digital “0”, the respective switch is switched off (i.e. the switch is open). The logic signal associated with the first switch 41 is for example generated by a pull-up driver. The logic signals associated with the second switch 42 and the discharging switch 43 respectively, are for example generated by a PWM controller.

As explained in the previous figures, due to the switching behaviour of the respective switches, a leakage current is able to flow through the first resistive component 12 causing a voltage drop. This voltage drop is indicated in FIG. 4 by the solid line 44. The dotted line 45 represents the predetermined reference voltage representative of a short circuit of the transistor 2. In case that the voltage over the first resistive component 12 as indicated by solid line 44 exceeds the reference voltage 45, the leakage current running through the transistor 2 causes short circuit of the transistor.

During the period between t₀ and t₁, the first switch 8 and the second switch 13 are closed, because their respective signals are high as shown with lines 41 and 42. Via the first switch 8, a current is able through the first electrical path 7 to the gate G of the transistor 2. Likewise via the second switch 13, a current is able to flow through the second electrical path 11 to the gate G of the transistor 2. As a result, a relatively small leakage current flows through the first resistive component 12. At time t₁, the first switch 8 is switched off. Therefore, the leakage current running through the first resistive component 12 increases, and thus the voltage drop over the first resistive component increases as well at time t₁. This is indicated by an increase shown by line 44 at t₁. At time t₂, the second switch 13 is switched off and the discharging switch 15 is switched on. When switching off the second switch 13, the transistor 2 is switched to another state, e.g. the transistor 2 is switched off. At the same moment the discharging switch 15 is closed. In the closed state of the discharging switch 15, the discharging switch 15 discharges the gate G of the transistor 2. By discharging the gate G with the discharging switch 15, any remaining voltage is removed from the gate G, causing the leakage current to stop. Because the remaining voltage is removed from the gate G, the voltage drop over the first resistance component 12 has been reduced, as shown by line 44 at time t₂. This way, the control system provides a safer manner of controlling the transistor 2.

At time t₃, the first switch 8, the second switch 13 and the discharging switch 15 are switched on again. Therefore, the leakage current is able to run again through the transistor 2 causing the voltage drop over the first resistive component 12. The process between the period t₀-t₃ is repeated between time window t₃-t₆.

During the time period between t₆ and t₇, the leakage current flowing through the transistor 2 could cause a short circuit. Because the first switch 8 is switched on, it is not detectable whether the transistor 2 experiences the short circuit. This is due to the rather low resistance value of the second resistive component 22 compared to the first resistive component 12. When the first switch 8 is opened at time t₇, it is illustrated that suddenly the voltage over the first resistive component 12 increases rapidly, as shown by line 44. The voltage over the first resistive component 12 exceeds the reference voltage 45. The leakage current detection system 32 as described in FIG. 3 is able to detect such incident, whereby the control system is adapted to anticipate more quickly to high leakage currents.

FIG. 5 schematically illustrates an embodiment of a flow diagram of the method according to for controlling a transistor 2 comprising a gate G, a source S and a drain D.

The method according to the invention comprises a first step 50 of supplying a first voltage via a first electrical path 7 to the gate G when the transistor 2 is in a first state. The first electrical path 7 is able to transfer a first voltage to the gate G of the transistor 2 when the transistor 2 is in a first state. The first voltage is for example supplied by a voltage supply 6. In the first state the transistor 2 for example is turned off.

The next step 51 of the method according to the invention comprises the switching the transistor 2 from the first state to a second state in response to the first voltage. Due to the applied first voltage at the gate G, the transistor 2 switches from the first state to a second state. In the second state, the transistor 2 for example turns on.

In case the transistor 2 is the second state, the first voltage is no longer provided to the gate via the first electrical path 7 (step 52)

In a further step 53 of the method according to the invention, a second voltage is supplied to the gate G via a second electrical path 11 when the transistor 2 is in the second state. The second electrical path comprises a first resistive component 12, for example a resistor. Further, the first electrical path 7 and the second electrical path 11 are at least partly in parallel to each other. Preferably, step 52 and step 53 occur almost simultaneously.

In step 54 of the method, a current is conducted via the second electrical path 11 to the gate G based on a leakage current of the transistor 2. In case the leakage current flows between the first resistive component 12 and the gate G, the leakage current induces a voltage drop across the first resistive component 12. The leakage current becomes higher when the temperature increases due to the forward current. Because the leakage current increases, the voltage drop over the first resistive component 12 becomes higher. As a result, the voltage at the gate G decreases, which helps to reduce the leakage current. In case the leakage current reaches a dangerous level for the transistor 2, the associated voltage drop across the first resistive component 12 causes the transistor 2 to switch from the second state to the first state. Because the transistor 2 is automatically switched off when the leakage current becomes too high, the invention improves the safety and lifetime relating to the transistor.

1. A control system for controlling a transistor comprising a gate, a source and a drain, the control system comprising:
a gate connector connectable to the gate of the transistor;
a voltage connector connectable to a voltage supply;
a first electrical path extending from the voltage connector to the gate connector;
a second electrical path extending from the voltage connector to the gate connector, wherein the second electrical path comprises a first resistive component, wherein the first electrical path and the second electrical path are at least partly parallel to each other;
wherein the control system further comprises a control unit which is adapted to:
connect the voltage supply to the gate via the first electrical path to allow the voltage supply to supply a first voltage via the first electrical path to the gate connector when the transistor is in a first state;
control the voltage supply to apply the first voltage via the first electrical path to the gate connector to switch the transistor from the first state to a second state;
disconnect the voltage supply and the gate from each other via the first electrical path when the transistor is in the second state;
connect the voltage supply to the gate via the second electrical path to allow the voltage supply to supply a second voltage via the second electrical path to the gate connector when the transistor is in the second state;
control the voltage supply to apply the second voltage via the second electrical path to the gate connector, wherein the second electrical path is adapted to conduct a current from the voltage connector via the first resistive component to the gate connector based on a leakage current of the transistor.

2. The control system according to claim 1, wherein the first resistive component is arranged to reduce, in response to the current, a gate voltage at the gate connector to a value lower than the first voltage to switch the transistor from the second state to the first state.

3. The control system according to claim 1, wherein the control system further comprises a first switch arranged in the first electrical path to connect the voltage supply to the gate via the first electrical path.

4. The control system according to claim 3, comprising a pull-up driver, wherein the first switch is controlled by the pull-up driver adapted to generate a pulse to switch the first switch.

5. The control system according to claim 1, wherein the first electrical path comprises a second resistive component.

6. The control system according to claim 5, wherein the second resistive component has a lower resistance value than the first resistive component.

7. The control system according to claim 5, wherein the resistance value of the second resistive component is between 1-10 Ohm, preferably between 1-5 Ohm.

8. The control system according to claim 1, wherein the resistance value of the first resistive component is between 100-2000 Ohm, preferably between 500-1500 Ohm.

9. The control system according to claim 1, wherein the first electrical path and the second electrical path are arranged in serial connection to the gate of the transistor.

10. The control system according to claim 1, wherein the control system further comprises a second switch arranged in the second electrical path to connect the voltage supply to the gate via the second electrical path.

11. The control system according to claim 1, wherein the control system further comprises a leakage current detection system configured to determine the leakage current of the transistor based on a voltage over the first resistive component.

12. The control system according to claim 11, wherein the leakage current detection system is configured to provide a signal representative of the leakage current of the transistor to the control unit, wherein the control unit is configured, in response of the signal, to switch the transistor from the second state to the first state.

13. The control system according to claim 12, wherein the signal representative of the leakage current of the transistor is representative of a short circuit of the transistor.

14. The control system according to claim 1, wherein the transistor is a HEMT, preferably a GaN HEMT.

15. The control system according to claim 1, the control system further comprises a discharging switch arranged between the first electrical path and/or the second electrical path and a ground to connect the first electrical path to the ground and/or to connect the second electrical path to the ground.

16. An electric vehicle, comprising the control system according to claim 1.

17. The electric vehicle according to claim 16, comprising an inverter or power converter and at least one of a drive train and a solar panel,
wherein the inverter or power converter comprises the transistor,
wherein the drive train is for providing power to drive the electric vehicle, and
wherein the solar panel is for generating electric energy based on solar energy,
wherein the inverter or power converter is adapted to exchange electric energy with at least one of the drive train and the solar panel.

18. A method for controlling a transistor comprising a gate, a source and a drain,
the method comprising the steps of:
supplying a first voltage via a first electrical path to the gate when the transistor is in a first state;
switching the transistor from the first state to a second state in response to the first voltage;
stop providing the first voltage to the gate via the first electrical path when the transistor is in the second state;
supplying a second voltage to the gate via a second electrical path when the transistor is in the second state, wherein the second electrical path comprises a first resistive component, and wherein the first electrical path and the second electrical path are at least partly in parallel to each other;
conducting a current via the first resistive component to the gate based on a leakage current of the transistor.

19. The method according to claim 18, further comprising the step of:
determining the leakage current of the transistor based on a voltage over the first resistive component.

20. The method according to claim 19, wherein the step of determining the leakage current of the transistor based on a voltage over the first resistive component comprises comparing the voltage over the first resistive component with a reference voltage representative of a short circuit of the transistor.

21. The method according to claim 20, further comprising the step of:
reducing a gate voltage at the gate to a value lower than the second voltage to switch the transistor from the second state to the first state after determining the leakage current.

22. The method according to claim 21, further comprising the step of:
creating a voltage drop over the first resistive component in response to the current to reduce the gate voltage.
